(19) United States
(12) Patent Application Publication
(10) Pub. No.: US 2020/0312741 A1
(43) Pub. Date: Oct. 1, 2020

(54) THERMOELECTRIC COOLER TO ENHANCE THERMAL-MECHANICAL PACKAGE PERFORMANCE

(71) Applicant: Intel Corporation, Santa Clara, CA (US)

(72) Inventors: Zhimin Wan, Chandler, AZ (US); Krishna Vasanth Valavala, Chandler, AZ (US); Chandra Mohan Jha, Chandler, AZ (US); Shankar Devasenathipathy, Tempe, AZ (US)

(73) Assignee: Intel Corporation, Santa Clara, CA (US)

(21) Appl. No.: 16/362,961

(22) Filed: Mar. 25, 2019

(51) Int. Cl. H01L 23/38; H01L 23/373; H01L 35/32

(52) U.S. Cl. CPC H01L 23/38; H01L 35/32; H01L 23/3735

(57) ABSTRACT

An IC package comprising a substrate comprising a dielectric, an IC device coupled to the substrate; and a thermoelectric cooling (TEC) device adjacent to the IC device and coupled to the substrate. A thermal trace extends laterally on or within the dielectric between the TEC device to the IC device, and the thermal trace is coupled to the TEC device and the IC device.

### BACKGROUND

Thermal management in integrated circuit (IC) packaging containing single or multiple integrated circuit (IC) devices is becoming an increasingly important issue. Packaging for modem high-performance integrated circuit devices must contend with increasingly larger scale microelectronic circuit integration, including vertical integration of multiple integrated circuit devices. Smaller form factors are associated with increasingly higher power densities, having concomitant heat transfer challenges. High-performance IC devices, such as modern multi-core microprocessor and high-bandwidth memory dies, commonly produce hotspots in the die-substrate interconnect level by large current draw through individual signal and power interconnects.

Heat conduction through-the die itself is relied upon to remove heat from the hotspot to an integrated heat spreader (IHS) and/or a thermal solution on the top of the integrated heat spreader. IC devices generally undergo numerous temperature excursions during their lifetimes, and experience frequent warpage that leads to mechanical stress on thermal interface materials due to thermal mismatch between an IHS and IC device, or between the IHS and heat sink. The frequent warpage may eventually lead to break down of the integrity of thermal interface materials between the IC device and an integrated heat spreader or heat sink, particularly at the corners of the IC device. Loss of thermal interface material integrity in the corner regions may lead to hot spots in the corners of the IC device. This is particularly important for microprocessors when in burst mode. Demand for higher microprocessor performance in video and gaming applications where repeated or extended bursts are required has necessitated development of advanced thermal management architectures at the package level.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A illustrates a cross-sectional view in the x-z plane of an integrated circuit (IC) package, according to some embodiments of the disclosure.

FIG. 1B illustrates a plan view in the x-y plane of an IC package, showing an exemplary arrangement of first level interconnects on a package substrate, according to some embodiments of the disclosure.

FIG. 1C illustrates a cross-sectional view in the x-z plane of a TEC module, according to some embodiments of the disclosure.

FIG. 1D illustrates a plan view in the x-y plane of a TEC module, according to some embodiments of the disclosure.

FIG. 2 illustrates a cross-sectional view in the x-z plane of an implementation of an IC package comprising a TEC module adjacent to an IC device, according to some embodiments of the disclosure.

FIG. 3 illustrates a process flow chart for an exemplary method for fabricating an IC package according to some embodiments of the disclosure.

FIGS. 4A-4H illustrate successive operations of the process flow summarized in FIG. 3, showing cross-sectional views in the x-z plane of evolving structure of an IC package, according to some embodiments of the disclosure.

FIG. 5 illustrates a block diagram of computing device comprising an IC package including an integrated TEC module mounted within the IC package adjacent and thermally coupled to an IC device as part of a system-on-chip (SoC) package in an implementation of a computing device, according to some embodiments of the disclosure.

### DETAILED DESCRIPTION

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

An integrated circuit (IC) package comprising discrete thermoelectric cooler modules (TEC modules) for enhanced thermal management of hot spots on adjacent IC devices is disclosed. Described embodiments include one or more TEC modules integrated into an IC package, adjacent to an IC device such as an IC die or an IC package. An example is a high-performance microprocessor (CPU), wherein the TEC is thermally coupled to the IC device by thermal traces extending between the IC device and the TEC. In some embodiments, the TEC module is attached to a package substrate adjacent to an IC device by solder bonding. In some embodiments, the thermal traces are deposited on the surface of a substrate dielectric. In some embodiments, the thermal traces are embedded under the surface of the dielectric and are interconnected by vias that extend to bond pads on the surface of the dielectric.

Hot spots within the active layer of an IC device may occur during periods of high levels of device activity, such as during bursts of computational processing. During burst periods, the frequency of instruction cycles increases, and power demand increases due to the sudden rise in the number of transistors recruited to operate, causing large current draw and increased heat dissipation. As the operations may be concentrated in a small portion of the die real estate where a particular high-density circuit is located, all of the power dissipation may be confined to a small region of the IC device. Hence, a hot spot may develop. By way of example, hot spots having dimensions of approximately 1 mm×2 mm (e.g., 2 mm²) may be burdened with dissipating ˜2 W of heat, which is equivalent to power densities of 1 kilowatt (kW)/cm² or higher. With such levels of power dissipation, hot spot temperatures may reach 100° C. or higher, enough to thermally stress the integrated circuitry and exceed the operational and mechanical temperature ratings of the devices contained by the circuitry (e.g., transistors, resistors and capacitors). Circuit design software that may be employed for chip design may predict the location of potential hot spots within the integrated circuity.

According to some embodiments, the disclosed package comprises thermal bond pads and traces for rapid conduction of heat away from the region of a potential hot spot where an IC device may be attached by flip-chip (e.g., C4) bonding. In some embodiments, an array of C4 bond pads may be fabricated on the package substrate to receive a ball grid array (BGA) on the front (active) side of an incoming IC device (die or package) that is to be flip-chip mounted on the substrate. Thermal bond pads may have a larger diameter than bond pads destined for signal routing. Thermal bond pads may or may not carry power, but have large diameters to accommodate transport of thermal energy to vias that may extend below the thermal bond pads, where the vias are coupled to one or more buried thermal traces that extend laterally within the dielectric material of the substrate. In some embodiments, thermal traces may be entirely on the surface of the package dielectric.

In some embodiments, the thermal trace extends between a first thermal bond pad and a second thermal bond pad on the package substrate surface. The first bond thermal pad may be solder-bonded to a thermal pad on IC device (e.g., a thermal pad is exclusively employed for heat conduction and not part of the electrical signal routing circuitry), and the second thermal bond pad may be solder bonded to a TEC module adjacent to the IC device. In some embodiments, the second bond pad may be solder-bonded directly to a thermoelectric element of the TEC module. In some embodiments, a thermoelectric element is a thin-film block of p-type or n-type thermoelectric material that is solder-bumped).

In some embodiments, the TEC module is a discrete component, such as a surface-mount Peltier element. In some embodiments, the TEC module may be attached to the package substrate surface by a thermally-conductive adhesive. As an example, the TEC module may have ceramic plates, or plates made from other electrically insulating materials over both the hot and cold junctions that are to interface with a heat transfer surface. In some embodiments, the plates may be copper-clad, enabling solder-bonding of the TEC module to an array of thermal pads on the substrate. The thermal trace may form a thermal conduit bridging the cold junction of the TEC to the hot spot on the adjacent IC die.

According to some embodiments, the thermal traces coupling the TEC module to the IC die may have a thickness that is substantially greater than the thickness of a signal routing trace to present a low thermal resistance to the heat flux traversing through the length of the trace. Thicknesses may range from 35 to 100 microns.

Here, the term “die” generally refers to a carrier structure for an integrated circuit. The term “die” implies a single unit, to be distinguished from the plural “dice”. Throughout this specification, however, the term “dies” will be used as the plural form of “die”. A number of identical dies may be “singulated”, or diced from a semiconductor wafer, such as a silicon wafer, by mechanical sawing or laser cutting.

Here, the term “package” generally refers to a structure including one or more integrated circuit dies bonded to a suitable substrate, such as a printed circuit board or embedded in a layered substrate (e.g., a bumpless build-up layer (BBUL) package). In common vernacular, an integrated circuit package may be referred to as a “chip”, although the term “chip” technically refers to a die in the package. The one or more dies may be encapsulated for protection from the environment in a dielectric material, such as an epoxy resin or a ceramic composite, which is molded into a block. Alternatively, the package may be without encapsulation, allowing the one or more dies to be exposed. The substrate generally comprises electrical interconnects on its bottom surface, which may be a pin array for insertion into a socket, or electrical contact pads for permanent solder-bonding to a printed circuit board, such as a computer motherboard or daughterboard.

Here, the term “assembly” generally refers to an integrated circuit structure or device comprising one or more packages and other components. An example is a stack of separate integrated circuit packages, where one package may be contain a microprocessor and a second package may contain a high-speed memory chip. The package stack may be attached to a common substrate and encapsulated, forming a self-contained package-on-package (PoP) device.

Here, the term “device” generally refers to a integrated circuit package or a single die.

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The term “microprocessor” generally refers to an integrated circuit (IC) package comprising a central processing unit (CPU) or microcontroller. The microprocessor package is referred to as a “microprocessor” in this disclosure. A microprocessor socket receives the microprocessor and couples it electrically to the PCB.

The vertical orientation is in the z-direction and it is understood that recitations of “top”, “bottom”, “above” “over” and “below” refer to relative positions in the z-dimension with the usual meaning. Generally, “top”, “above”, and “over” refer to a superior position on the z-dimension, whereas “bottom”, “below” and “under” refer to an inferior position on the z-dimension. The term “on” is used in this disclosure to indicate that one feature or object is in a superior position relative to an inferior feature or object, and in direct contact therewith. However, it is understood that embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional”, “profile”, “plan”, and “isometric” correspond to orthogonal planes within a cartesian coordinate system. Thus, cross-sectional and profile views are taken in the x-z plane, plan views are taken in the x-y plane, and isometric views are taken in a 3-dimensional cartesian coordinate system (x-y-z). Where appropriate, drawings are labeled with axes to indicate the orientation of the figure.

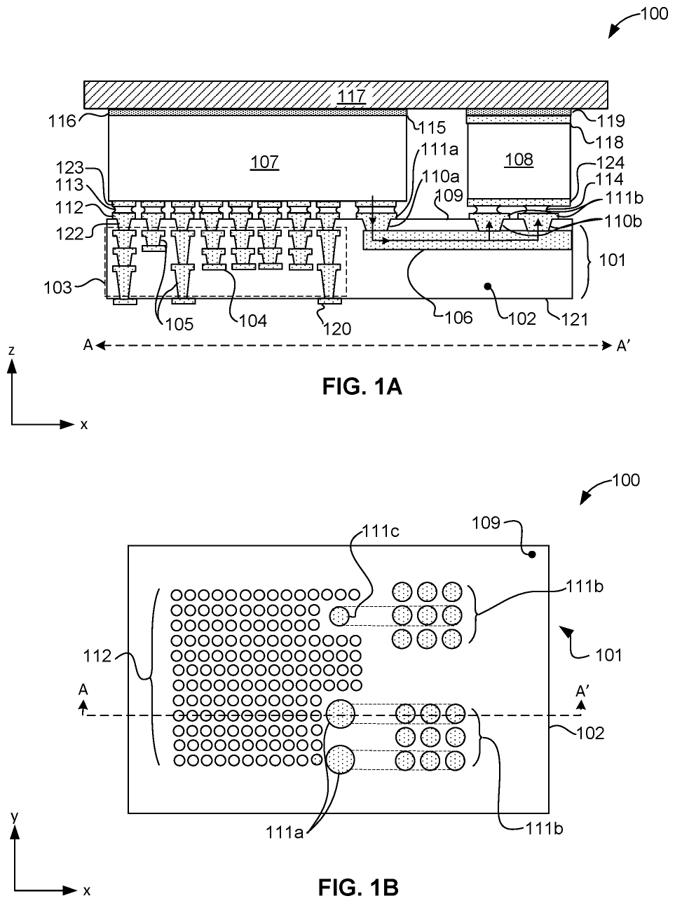

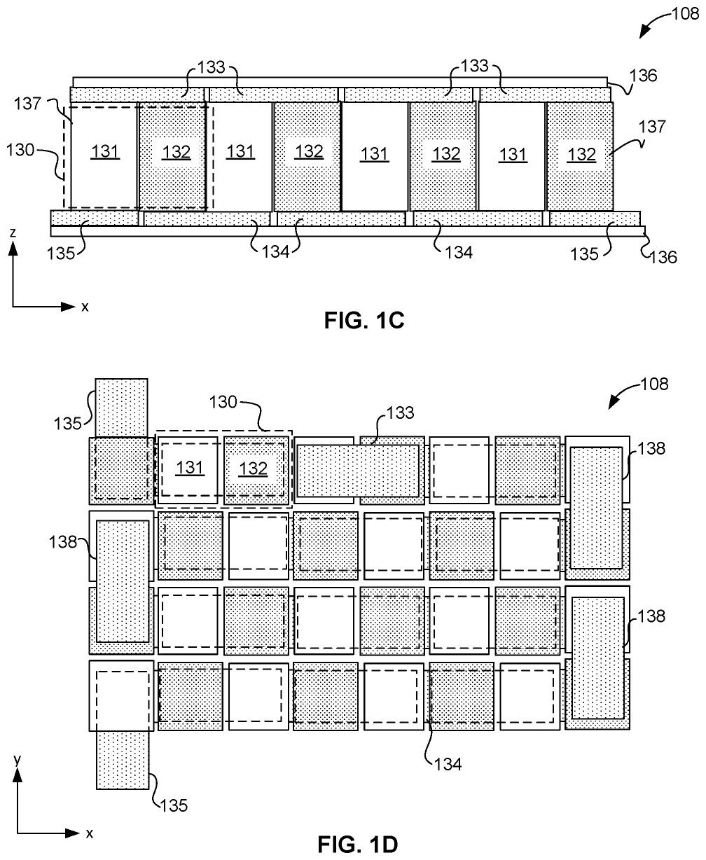

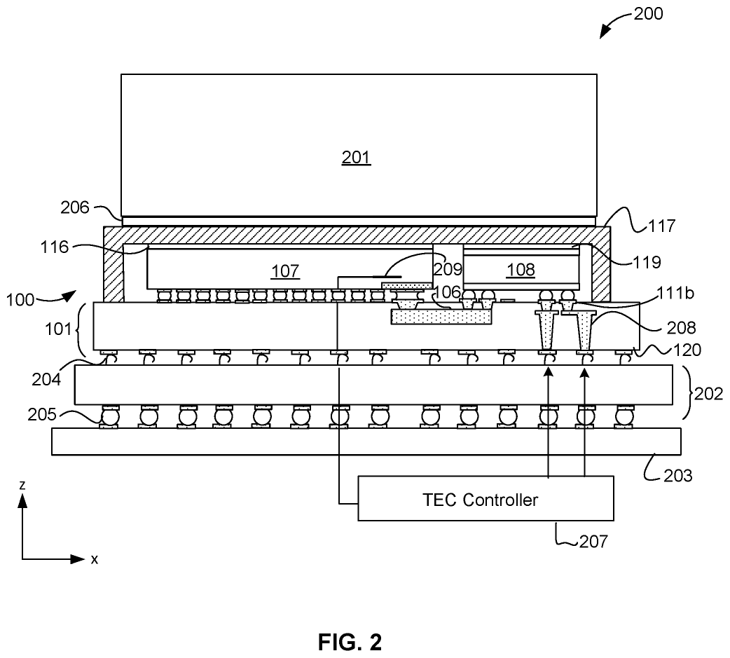

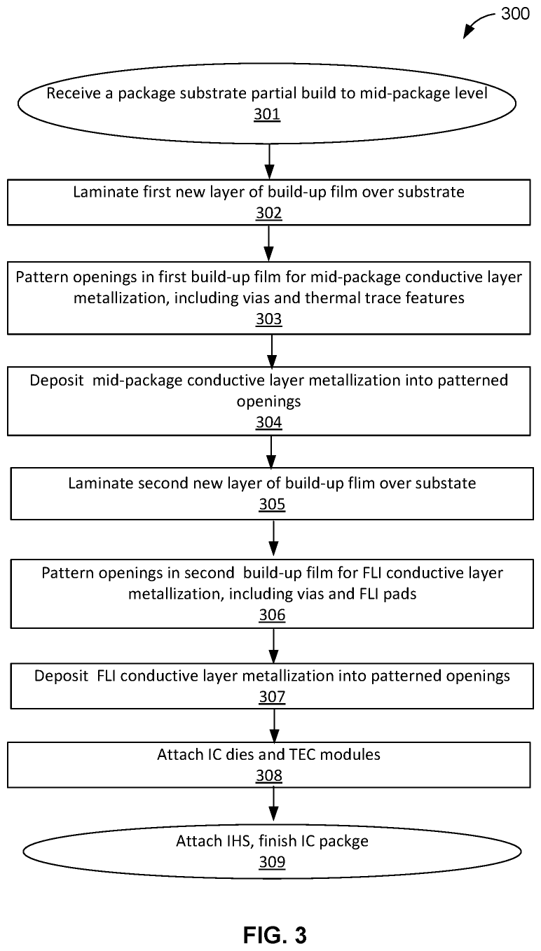

FIG. 1A illustrates a cross-sectional view in the x-z plane of integrated circuit (IC) package 100, according to some embodiments of the disclosure.

The cross-sectional view shown in FIG. 1A is taken along section line A-A′ in FIG. 1B. IC package 100 comprises multi-level substrate 101, comprising dielectric 102 and multiple layers of metallization structures 103 for signal (e.g., data) and power routing (delineated by the dashed outline) within dielectric 102. In some embodiments, substrate 101 is a bumpless build up layer (BBUL) substrate comprising laminates of dielectric 102 between conductive layers comprising metallization structures 103. Metallization structures 103 may comprise signal traces or pads 104 and signal vias 105. In some embodiments, signal traces or pads 104 and signal vias 105 carry power. In some embodiments, the BBUL substrate architecture comprises a core with build-up layers on both sides of the core. In the illustrated embodiment, substrate 101 is a coreless substrate structure, where layers of dielectric laminates may be built up on a removable carrier substrate (described below). In some embodiments, dielectric 102 is a molded resin, such as, but not limited to, an epoxy or epoxy composite.

IC package 100 comprises thermal trace 106 that is shown extending between IC device 107 and adjacent TEC module 108. IC device 107 may be an IC die or an IC package. In the illustration, IC device and TEC module 108 are shown as partial structures, and may extend further in the x direction than indicated in the figure. In the illustrated embodiment, thermal trace 106 is a buried structure. In some embodiments thermal trace 106 is disposed entirely on the surface 109 of substrate 101.

Thermal vias 110 (e.g., 110a and 110b, collectively as thermal vias 110) extend between thermal bond pads 111 (e.g., thermal pads 111a and 111b, respectively; collectively as thermal pads 111) on surface 109 and trace 106 and may materially couple thermal trace 106 to thermal pads 111. Thermal vias 110 may have a larger diameter than the diameter of data signal routing vias 105, as shown in FIG. 1A. The larger cross-sectional dimensions of the heat-conducting structures (e.g., thermal trace 106, thermal vias 110 and thermal bond pads 111) relative to data signal-routing structures (e.g., traces 104 and vias 105) presents a path of low thermal resistance to potentially large heat fluxes from IC device 107 to TEC module 108.

Signal routing vias 104 extend to signal pads 112 disposed on surface 109 of substrate 101, providing vertical interconnects from land pads 120 to IC device 107. First-level interconnects (FLIs) comprise thermal pads 111, signal pads 112, as these bond pads are both disposed on surface 109 in the first conductive layer of substrate 101.

In the illustrated embodiment, thermal trace 106 is shown to have a larger thickness (extending in the z-direction) than pads FLI pads 111 and 112, including buried pads 104, and any data routing traces that may be coupled to the FLI pads. As an example, buried pads 104 and FLI pads 111 and 112 may have a thickness of 15 microns. In some embodiments, thermal trace 106 has thicknesses ranging from 35 microns to 50 microns. The relatively large thickness of thermal trace 106 may be necessary for reducing thermal resistance to heat flux. During operation of the device, excess heat created at a hot spot in the active layer of IC device 107, in the vicinity of thermal pad 111a, may travel along the path indicated by the arrows in the figure. The indicated heat flux path comprises thermal pad 111a, thermal via 110a, thermal trace 106, to thermal vias 110b and thermal pads 111b, between the hot spot and TEC module 108. As mentioned above, the diameters of thermal vias 110a and 110b may be substantially larger than signal vias 105 to handle potentially large heat fluxes. Some of the data signal power dissipation may be relatively small in comparison to heat dissipated by circuity in the vicinity of a hot spot.

As an example, a hot spot may occupy an area of 1-2 mm². During a burst of computational activity, circuitry in the hot spot region may dissipate 2 watts or more of peak electrical power as excess heat. An equivalent power density of over 100 W/cm² may be generated. Thermal metallization (e.g., thermal trace 106 vias 110a and 110b) may have high thermal conductivity, and combined with a large cross-sectional area, may provide a low thermal resistance path for an excess heat flux of 100 W/cm² moving to TEC module 108. In some embodiments, thermal metallization may comprise high thermal conductivity (e.g., high-k, where k is the coefficient of thermal conductivity) metals, such as, but not limited to, copper, silver, gold, aluminum. In alternate embodiments, thermal metallization comprises high-k electrical insulators such as, but not limited to, aluminum nitride. The afore-mentioned materials may exhibit a minimum thermal conductivity (k) of 140 W/mK for aluminum nitride to approximately 400 W/mK for copper and silver.

In some embodiments, TEC module 108 is a discrete device comprising a semiconducting thermoelectric material sandwiched between two metal/semiconductor junctions on opposing surfaces, comprising electrodes 118 and 124. In many implementations, the compartmentalized material is arranged into an array of alternating p-type and n-type islands that are interconnected by metal electrodes spanning between adjacent p-type and n-type islands, where adjacent p-type and n-type islands form thermoelectric pairs. TEC module 108 may comprise an array of interconnected thermoelectric pairs. This arrangement is described in greater detail below and shown in FIGS. 1C and 1D.

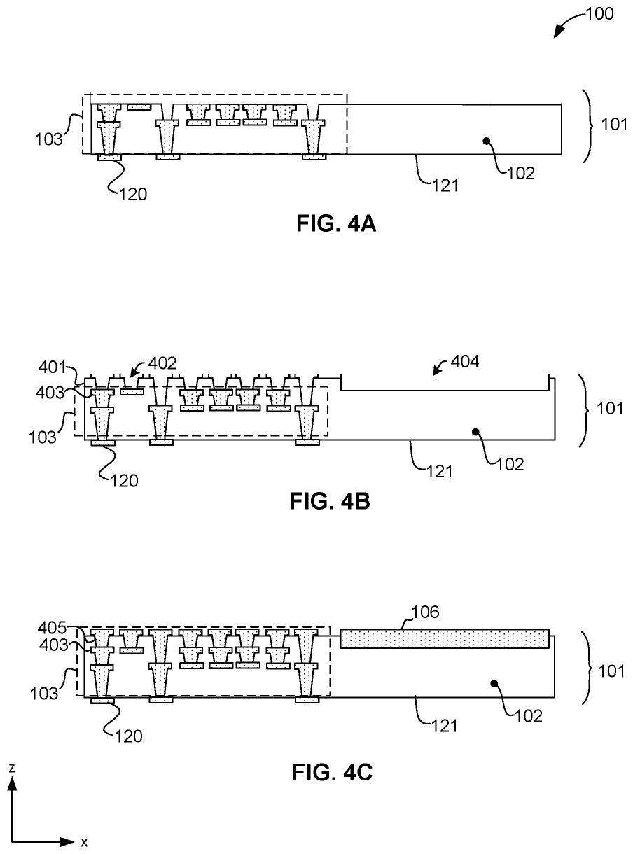

IC device 107 is solder-bonded to first-level interconnects (FLIs) 112 by solder joints 113. FLIs may comprise bond pads and traces on the surface of substrate 101. FLIs may also comprise thermal bond pads 111, to which TEC module 108 is bonded by solder joints 114. In some embodiments, TEC module 108 is bonded to thermal bond pads by a conductive adhesive. In some embodiments, IC device 107 backside 115 is in contact with thermal interface material (TIM) 116, which is interfaced to thermal solution 117. In some embodiments, thermal solution 117 is an integrated heat spreader (IHS). IHS 117 may comprise sidewalls (not shown; see FIG. 2) extending in the z-direction from the lid portion show in the figure. In alternate embodiments, thermal solution 117 is a heat sink. In some embodiments, thermal solution 117 is a cold plate. In some embodiments, thermal solution 117 comprises IHS interfaced to a heat sink (see FIG. 2).

Similarly, upper junction 118 of TEC module 108 is interfaced with TIM 119, which is sandwiched between upper junction 118 and thermal solution 117. During operation of the TEC module 108, upper junction 118 may be a hot junction, where heat pumped by TEC module 108 is rejected to a heat dissipation structure. In the illustrated embodiment, heat is rejected to thermal solution 117, which as a heat sink may dissipate the heat to the ambient environment. TIMs 116 and 119 may decrease thermal resistance between backside 115 of IC device 107, and upper junction 118, respectively, with thermal solution 117, by filling gaps in the interface with relatively high thermal conductivity (e.g., high-k) malleable material. In some embodiments, TIMs 116 and 119 is a thermal grease or gel. In some embodiments, TIM 119 is a thermal pad or solder. In some embodiments, TIM 119 has a thermal conductivity of at least 0.3 W/mK.

Land pads 120 are bottom-level interconnects disposed on the bottom surface 121 of substrate 101. Land pads 120 may comprise bond pads for mounting IC package 100 in a socket, where land pads 120 are contacted to a pin array or directly surface mounting to a printed circuit board, such as a motherboard of a computer. Power and data signals may be routed into IC package 100 through land pads 120. Power to IC package 100 may be routed to power rails (not shown) on substrate 101 that distribute power connections (positive voltage and ground) to devices within IC package 100. In some embodiments, power to TEC module 108 may be directly routed through land pads that are not shown in the plane of the figure (e.g., power connection pads that are above or below the x-z plane of the figure). In some embodiments, power to TEC module 108 may be routed from a general power rail on or within substrate 101 (not shown). In some embodiments, some land pads 120 are coupled to power terminals of TEC module 108 (not shown, see FIG. 1B).

FIG. 1B illustrates a plan view in the x-y plane of IC package 100, showing an exemplary arrangement of first level interconnects (FLIs) on surface 109 of substrate 101, according to some embodiments of the disclosure.

In FIG. 1B, IC device 107 and TEC module 108 are omitted in IC package 100 to illustrate an exemplary distribution of FLI pads comprising data signal pads 112 and thermal pads 111a, 111b and 111c. Thermal pads 111a and 111c are positioned in the array of data signal pads 112, and both may bond to complimentary thermal pads on an IC die (e.g., IC device 107). Thermal pads 111a are distinguished from thermal pads 111c in size and location only. Thermal pads 111c are not shown in FIG. 1A, as they may be below the plane of FIG. 1A. In the illustrated embodiment, thermal pads 111b are arranged in small square arrays comprising nine pads each for bonding TEC modules. The particular arrangements shown in the figure are not meant to be limiting, but to be exemplary. The number of thermal pads is not limited to the number shown in the illustrated embodiment, and may be any suitable number. Any suitable arrangement of pads may be employed, where the arrangement may be determined by the shape of the particular TEC module chosen. TEC modules (e.g., TEC module 108) may be solder-bumped and attached by flip-chip or similar methods.

In the left-hand portion of the figure, a large array of data signal pads 112 is shown, where the particular arrangement illustrated is exemplary. Other suitable arrangements are entirely possible. The illustrated arrangement and other suitable arrangements generally have little to no bearing on the removal of excess heat evacuation function of thermal pads 111a. The packed arrangement of data signal pads 112 in the vicinity of thermal pads 111a and 111c may coincide with a region high-density data processing circuitry in the active layer of an attached IC die (e.g., IC device 107). Thermal pads 111a and 111c are placed in the midst of data signal pads 112 where TIM degradation and thus potential hot spots may occur during operation of the device. Generation of excess heat may be confined to the region of substrate 101 in the vicinity (e.g., immediately surrounding) thermal pads 111a and 111c. Excess heat generated by the hot spots may be collected by thermal pads 111a and 111c by conductive flux through the IC die interconnects to thermal pads 111a and 111c.

In the illustrated embodiment, thermal traces (e.g., thermal trace 106) are shown as buried structures within dielectric 102, as shown in FIG. 1A, indicated by the hidden lines extending between thermal pads 111a and pads in the lower array of thermal pads 111b, and between thermal pads 111c and pads in the upper array of thermal pads 111b. In some embodiments, thermal traces 106 are on top surface 109, and in the FLI level. The indicated thermal traces have widths that are approximately equivalent to the diameter of thermal pads 111b. Diameters of thermal pads 111b may range from 100 microns to 1000 microns.

FIG. 1C illustrates a cross-sectional view in the x-z plane of TEC module 108, according to some embodiments of the disclosure.

TEC module 108 is represented schematically in FIG. 1C as a thermoelectric assembly comprising multiple thermoelectric pairs 130, as indicated by the dashed outline. As shown in FIG. 1D and described below, thermoelectric pairs 130 are distributed in a two-dimensional array. Thermoelectric pairs 130 comprise a p-type region 131 adjacent to a n-type region 132, and are the building blocks of TEC module 108. Adjacent p-type element 131 and n-type element 132 are electrically interconnected by electrodes 133. In the illustrated embodiment, any pair of adjacent p/n elements may be a thermoelectric pair. Neighboring thermoelectric pairs 130 are electrically interconnected in series by electrodes 134 on an opposing side. In some embodiments, thermoelectric pairs may be shifted by one element, where adjacent p/n elements are interconnected in series by electrodes 134, and adjacent thermoelectric pairs may be electrically interconnected by electrodes 133.

In some embodiments, the thermoelectric material is a doped semiconducting material, having either p-type or n-type conductivity. Suitable thermoelectric materials include, but are not limited to, bismuth chalcogenides, such as bismuth telluride (Bi₂Te₃) and bismuth selenide (Bi₂Se₃), antimony chalcogenides such as antimony telluride (Sb₂Te₃); bismuth-antimony chalcogenide alloys, such as p-type BiₓSb₍₂₋ₓ₎Te₃ and n-type Bi₂Te₍₁₋ₓ₎Seₓ; lead chalcogenides such as thallium-doped lead telluride (PbTe) and lead chalcogenide alloys such as p-type PbTe₍₁₋ₓ₎Seₓ, and n-type Pb₍₁₋ₓ₎SnₓTe. Suitable thermoelectric materials may further include clathrates such as Ba₈Ga₁₆Ge₃₀, or Ba₈Ga₁₆Si₃₀ and Ba₈Ga₁₆Al₃Ge₂₇; alloys of silicon-germanium (SiₓGe₍₁₋ₓ₎) such as Si_{0.8}Ge_{0.2}. Suitable thermoelectric materials may further include Skutterudite compounds such as (Co, Ni or Fe)(P, Sb or As) skutterudites, and rare earth-filled skutterudites such as Ir₄XGe₃Sb₉, where X is La, Nd or Sm. Suitable thermoelectric materials may further include transition metal oxides such as sodium cobaltite (NaₓCoO) and sodium cobaltate (Na_{0.8}CoO₂), zinc oxide (ZnO), manganese oxide (MnO₂) and niobium oxide (NbO₂), half Huesler compounds including NbFeSb, NbCoSn, VFeSb, strontium titanate/strontium oxide (SrTiO₃/SrO) Ruddlesden-Popper phase compounds. Suitable thermoelectric materials may further include amorphous systems such as Cu—Ge—Te, In—Ga—Zn—O, Zr—Ni—Sn, Si—Au and Ti—Pb—V—O. Other suitable thermoelectric materials are also possible. N-type and p-type doping of the materials may be done by introduction of heteroatoms or by alloy composition. Thermoelectric materials may have relatively low thermal conductivities (e.g., <1 W/mK).

When TEC module 108 is operated, power is applied across terminal electrodes 135. A current may flow within each thermoelectric element 131 and 132, where majority carriers in each element flow in the same direction. As an example, a positive voltage (with respect to ground) applied at terminal electrode 135 on the left side of the figure and a negative or ground voltage applied at terminal electrode 135 on the right side of the figure causes holes in the p-type elements (e.g., elements 131) and electrons in the n-type elements (e.g., elements 132) to flow from electrodes 134/5 to electrodes 133 (e.g., from bottom to top of the structure). Minority carriers flow in a direction opposite to the majority carriers (e.g., from top to bottom of the structure), creating electron current flow from right to left (or conventional current from left to right).

The Peltier effect is caused by majority carriers carrying heat from the bottom side of the structure, as viewed in the figure, to the top of the structure. In the described configuration, the bottom side comprising electrodes 134 is a cold junction, where heat may be absorbed from the environment or from a heat source in contact with the cold junction, and the top side comprising electrodes 133 is a hot junction, where heat transported by the majority carriers from the cold junction. The transported heat may be rejected to the environment or into a heat sink in contact with the hot junction.

In some embodiments, electrically-insulating plates 136 are disposed over the top and bottom sides of TEC 108, covering electrodes 133 and 134 on opposite sides. Plates 136 may electrically insulate electrodes 133 and 134 from contact with electrically conducting structures, which potentially could short circuit electrodes 133 together or electrodes 134 together on each side of TEC module 108, stopping current flow and defeating the Peltier effect. Plates 136 may comprise a ceramic or organic polymer composite material. Sidewalls 137 may be formed by thermal electric elements at the end of the row shown in the figure. The z-height of TEC module 108 may be substantially the same as sidewalls 137. Sidewalls 137 may have a z-height ranging between 100 microns and 1000 microns.

FIG. 1D illustrates a plan view in the x-y plane of TEC module 108, according to some embodiments of the disclosure.

The plan view in FIG. 1D shows an exemplary array of thermoelectric elements 131 and 132. Plates 136 are omitted to show the array details. The array is viewed from the top of the structure, as defined in FIG. 1C, showing electrodes 133 as dashed outlines (for transparency of view), spanning adjacent thermoelectric elements 131 and 132. Rows of thermoelectric elements may be connected in series, as shown in FIG. 1C, alternately on top by electrodes 133, and alternately on the bottom below the plane of the figure, by electrodes 134. Each row is connected in daisy-chained together (e.g., connected in series) by bridging electrodes 138 at the end of each row, where a serpentine electrical path is formed by the interconnection of rows at opposing ends. Terminal electrodes 135 are at the terminal ends of the serpentine current path.

FIG. 2 illustrates a cross-sectional view in the x-z plane of IC assembly 200, according to some embodiments of the disclosure.

IC assembly 200 is an exemplary installation of IC package 100 in a thermal mount that comprises heat sink 201, socket 202 and PCB 203. IC package 100 is mounted in socket 202, comprising contact pins 204 contacting land pads 120. Socket 202 may be bonded to PCB 203 by solder joints 205. PCB 203 may be a computer motherboard. IC package 100 comprises integrated heat spreader (IHS) 117 that interfaces internally with IC device 107 and TEC module 108 (through TIMs 116 and 119, respectively), and thermally couples die 107 and TEC module 108 to heat sink 201 through TIM 206. TIM 206 may be a high-k (e.g., k≥3 W/mK) thermal grease, gel or a solid malleable pad. IHS 117 may be bonded to substrate 101 by an adhesive for immobilization and secure attachment. IHS 117 may comprise materials including, but not limited to, copper, copper alloys, aluminum, aluminum alloys or steel alloys. In some embodiments, IC package 100 may include an overmold material to seal the entire contents of IC package 100 in an encapsulant for protection and stabilization of internal components.

IC assembly 200 comprises TEC controller 207 for powering TEC module 108. TEC controller 206 is coupled to TEC module 108 by vias 208 extending through substrate 101. Vias 208 couple land bond pads 120 to power-carrying thermal pads 111b, as indicated schematically by the arrowed leads extending from TEC controller 207 to vias 208. In some embodiments, TEC controller 207 is coupled to temperature sensor 209 that may be integrated into IC device 107, enabling a control loop. TEC controller 207 may be coupled to PCB 203 as a module or integrated circuit.

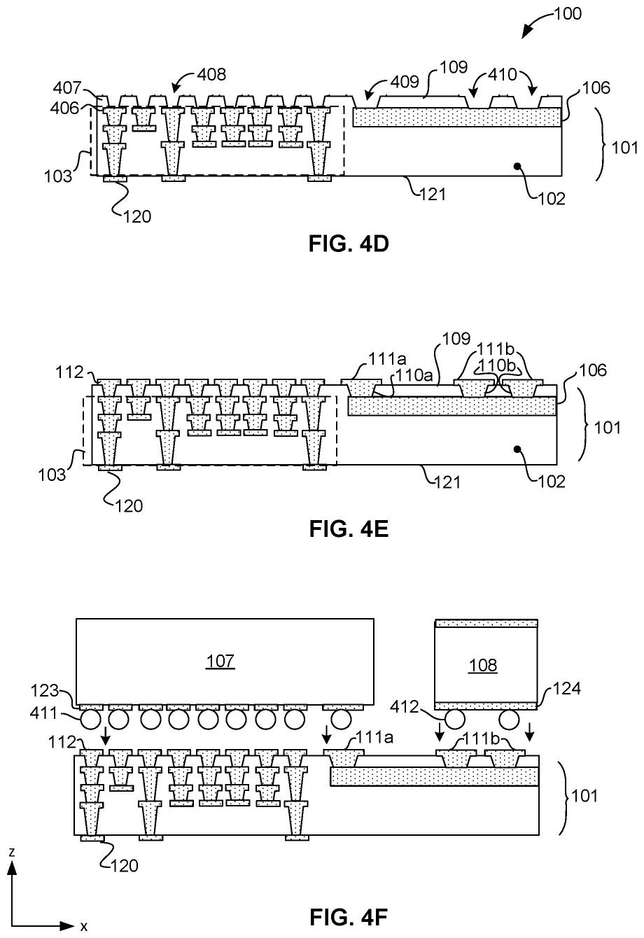

FIG. 3 illustrates process flow chart 300 for an exemplary method for fabricating IC package 100, according to some embodiments of the disclosure.

At operation 301, a partially built package substrate (e.g., substrate 101) is received. The substrate may comprise multiple embedded metallization levels between dielectric layers (e.g., for BBUL package), and be completed up to mid-package metallization. In the illustrated embodiment, the substrate is fabricated by a bumpless build-up layer (BBUL) process. In some embodiments, the substrate comprises a molded resin, such as an epoxy resin.

At operation 302, a fresh layer of dielectric is laminated over the received substrate. The lamination process may be performed at elevated temperature. The dielectric laminates may comprise coper-clad epoxy resins sheets. The laminate may cover exposed metal structures deposited over the partially-complete substrate from a previous metallization operation.

At operation 303, the new layer of dielectric is patterned to form openings in the newly laminated dielectric layer. Openings within the dielectric layer may be formed by lithographic processes or by direct writing processes. For lithographic processes, a photoresist is deposited over the surface of the substrate and patterned by known lithographic techniques. In some embodiments, a thick resist is deposited for deep-reactive ion etching (DRIE) of the dielectric. In some embodiments, openings in the dielectric layer are formed by a wet etch process, for example, by an acid etch. Holes made by both wet etch and dry etch processes may have a conical or sloped walls due to lateral under-etch, where the opening sidewalls are attacked by the etchant during opening formation, and lateral as well as vertical etching takes place. Under-etch is more pronounced in wet etching, where dry etching can produce near-vertical sidewalls.

Direct write operations may include laser techniques, including, but not limited to, laser drilling. Laser drilling may be employed to form openings of various shapes, from circular to oval. A trench may be formed for deposition of a thermal trace by step-wise overlap drilling of a trench. A pulsed infrared-emitting (e.g., 1064 nm) neodymium yttrium aluminum garnet (Nd:YAG) laser may be employed, but other types of lasers (e.g., CO₂) that emit in the infrared may be equally employed. Holes drilled by laser beam may have a conical profile due to the radial Gaussian energy distribution of the beam, where energy is highest at the beam center and decreases toward the edges of the beam. Hence, ablation rates are larger in the center of the beam.

At operation 304, next-to-last metallization layer is deposited into the openings formed in the previous operation. Deposition of metal into the openings and over the surface of the dielectric (e.g., surface 109) may be performed by an electroplating operation. An electrically conducting (metal) seed layer may be deposited ahead of the electroplating process to provide a conductive surface that performs as a cathode during electroplating. As an example, a gold layer may be deposited before the electroplating step. In some embodiments, deposition of a metal into the openings is performed by an electroless deposition process. In preparation of an electroless deposition process, a catalyst, such as platinum chloride, may be deposited on the surface to initiate electroless deposition of a metal such as copper. In some embodiments, deposition of a metal into the openings and over the surface of the dielectric may be performed by a metal-organic chemical vapor deposition process.

In addition to formation of thick thermal traces within trenches, formation of pads and traces on electroplated vias may be formed by lateral overgrowth of electroplated vias when via openings fill to the top. In some embodiments, a through-mask electroplating process is employed to plate traces and pads through lithographically-defined openings in a photoresist mask.

At operation 305, a second new dielectric layer is laminated over the mid-substrate level metallization structures formed in the previous operation. Mid-substrate level metallization structures become buried structures by lamination of the dielectric over-layer. The lamination of the second new dielectric sheet may complete the substrate build-up process, and form the top layer of the package substrate (e.g., substrate 101).

At operation 306, openings may be formed in the second new dielectric layer in preparation of deposition of first-level interconnects (e.g., FLIs 111 and 112). Via holes are formed by processes named above (e.g., operation 303) over buried pads formed in operation 304, and may extend lower vias to the top surface.

At operation 307, vias (e.g., data signal routing/power vias 122, thermal vias 110a and 110b) are deposited into openings formed at operation 306. Processes named for operation 304 may be employed for this step, such as electroplating or electroless deposition. FLI structures (e.g. signal pads 112, thermal pads 111a and 111b) may be formed by lateral overgrowth of metal over the dielectric surface adjacent to via openings. In some embodiments, FLI structures may be formed by through-mask electrodeposition. Pad and trace features may formed in a photoresist as the electrodeposition mask. Formation of FLIs may be the final process operation for fabrication of the substrate (e.g., substrate 101).

At operation 308, die-attach processes may be employed to attach IC dies (e.g., IC device 107) and TEC modules (e.g., TEC module 108) onto the FLI structures formed at operation 307. As an example, flip-chip (C4) bonding may be employed for die attach. IC dies may be solder bonded to signal pads (e.g., signal pads 112 and TEC modules may be solder bonded to thermal pads (e.g., thermal pads 111).

At operation 309, an integrated heat spreader (e.g., IHS 117) may be attached to IC dies (e.g., IC device 107) and TEC modules (e.g., TEC module 108) attached to the substrate (e.g., substrate 101) at operation 308. The IHS may be positioned over the attached dies after a thermal interface material (e.g., TIM 116 and 119) is deposited over the top surface of the IC dies (e.g., back-side surface 115) and the hot junction of the TEC module (e.g., hot junction 118). The IHS may be transferred to the substrate and positioned by a pick-and-place operation. In some embodiments, the IHS is attached to the substrate dielectric by an adhesive. Attachment of the IHS completes assembly of the IC package (e.g., IC package 100).

In some embodiments, an over-mold is formed over the assembled package to encapsulate the attached structures, and stabilize the package. An over-mold may be formed by flowing a liquid resin into a mold containing the bare package. The over-mold material may comprise an epoxy resin and/or a fill material such as silica powder. The IHS lid may be exposed by a polishing operation to remove over-mold material that formed over the top of the IHS lid for exposing the lid material.

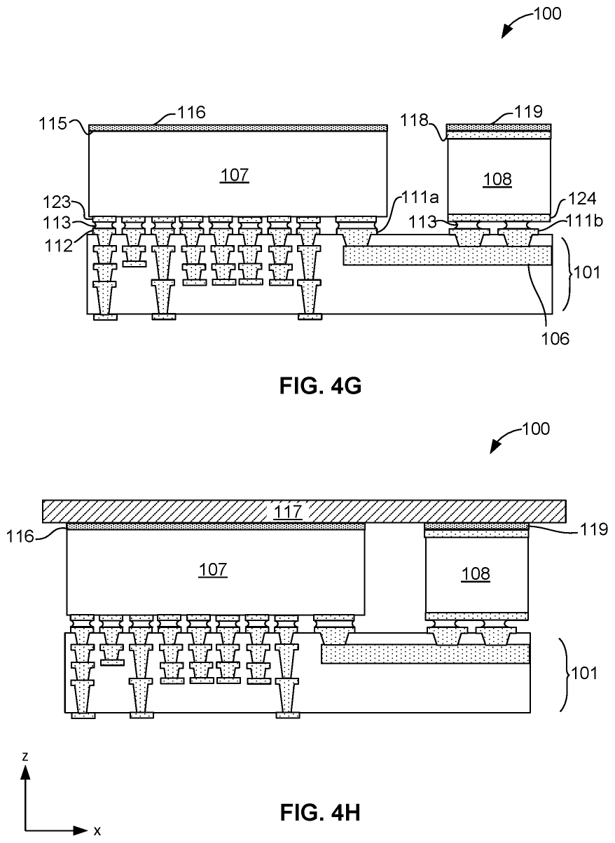

FIGS. 4A-4H illustrate successive operations of the process flow summarized in FIG. 3, showing cross-sectional views in the x-z plane of evolving structure of IC package 100, according to some embodiments of the disclosure.

In FIG. 4A, IC package 100 is received at an intermediate stage of fabrication as a partially complete substrate, (e.g., substrate 101), comprising dielectric 102, buried metallization structures 103 embedded in dielectric 102, and land pads 120 on bottom surface 121 of substrate 101. Substrate 101 may be formed by a BBUL process, where dielectric 102 is formed by lamination of dielectric sheets. Buried metallization 103 may be formed by patterning deposited metal (e.g., copper) layers formed over each laminate layer, as described below.

In FIG. 4B, the build-up process of IC package 100 is continued by addition a first new dielectric layer 401, which is laminated over partially completed substrate 101, covering any top-level metallization structures 103 exposed as received. Openings 402 are formed in dielectric layer 401 by methods described above (e.g., see description of operation 303 in FIG. 3). Openings 402 are formed over buried pads 403 in preparation for mid-package metallization structures via formation by metal (or a suitable inorganic or organic electrical conductor) deposition into the holes. Trench 404 is formed in preparation of deposition of a thermal trace (e.g., thermal trace 106). The depth of trench 404 may be approximately equal to the thickness of the thermal trace that is to be formed within trench 404.

In FIG. 4C, metallization 103 is augmented by formation of mid-substrate level vias 405 and pads 406 are formed by deposition of a metal (e.g., copper) into openings 402. Metal deposition techniques have been enumerated above. Pads 406 may be formed by lateral overgrowth from the tops of the vias 405. Thermal trace 106 is formed by filling trench 404 with a suitable metal such as, but not limited to, copper, gold, silver or aluminum. In some embodiments, an electrically insulating but thermally conductive material, such as, but not limited to, aluminum nitride, is employed to grow thermal trace 106. Thermal trace 106 may be overgrown so that it is approximately flush with pads 406, and may extend laterally over the surface of dielectric 102. The thickness of thermal trace 106 is in substantially determined by the depth of trench 404.

In FIG. 4D, a second dielectric layer 407 is laminated onto substrate 101 as the top dielectric layer stack having top surface 109. In preparation of formation of FLI metallization, signal FLI via openings 408 are made in second dielectric layer 407 by methods described above, and are aligned with pads 406. Thermal via openings 409 and 410 are likewise formed over thermal trace 106, where thermal via opening 409 may be positioned with the array of signal FLI via openings 408 in the vicinity of a potential hot spot during operation of an IC die (e.g., IC device 107) that is to be attached to bond pads (e.g. bond pads 112) that are to be formed in a subsequent operation over vias (e.g., signal vias 122) to be deposited within openings 408. Thermal via openings 410 may be positioned over thermal trace 106 adjacent to openings 408, in preparation for formation of thermal pads 111, to which a TEC module (e.g. TEC module 108) is to be bonded.

In FIG. 4E, FLI vias 122 and bond pads 112 are formed by deposition of conductive material into openings 408-410, along with thermal vias 110a, 110b, and thermal pads 111a and 111b. FLIs and supporting vias (e.g., vias 110 and 122) may be electroplated into openings employing techniques described above. Fabrication of substrate 101 may be completed in this operation. In the illustrated embodiment, substrate 101 is vertically grown from land-side surface 121 having land pads 120, to FLIs 111 and 112 on top surface 109.

In FIG. 4F, IC device 107 and TEC module 108 are positioned over FLIs 112 and 111, respectively in preparation for C4 (e.g., flip-chip) bonding of both devices onto substrate 101. In the illustrated embodiment, IC device 107 and TEC module 108 are transferred to substrate 101 by a pick and place operation, as indicted by the downward-pointing arrows. A ball grid array (BGA) 411 is formed on IC die pads 123 by a bumping process. Similarly, TEC module 108 may be solder-bumped to produce BGA 412 on electrode 124.

In FIG. 4G, BGAs 411 and 412 of FIG. 4F are reflowed to form solder joints 113, soldering IC device 107 and TEC module 108 to substrate 101. After reflow, an underfill (not shown) may be added by capillary action (e.g., a capillary underfill) between substrate 101 and IC device 107 and TEC module 108, between solder joints 113. The underfill (not shown) may stabilize solder joints 113 and adhere IC device 107 and TEC module 108 to substrate 101. By means of solder joints 113, TEC module 108 is thermally coupled to IC device 107 through thermal trace 106. TIMs 116 and 119 may be formed on backside surface 115 of IC device 107, and on hot junction 118 on TEC module 108. TIMs 116 and 119 may be a thermal grease or gel that is printed over surfaces such as die backside 115 and hot junction 118 that are to interface with an IHS or a heat sink.

In FIG. 4H, IHS 117 is attached to substrate 101 such that IHS 117 contacts TIMs 116 and 119. Attachment of IHS 117 may be performed by a pick and place operation. IHS 117 may have sidewalls that are attached to substrate 101 by an adhesive.

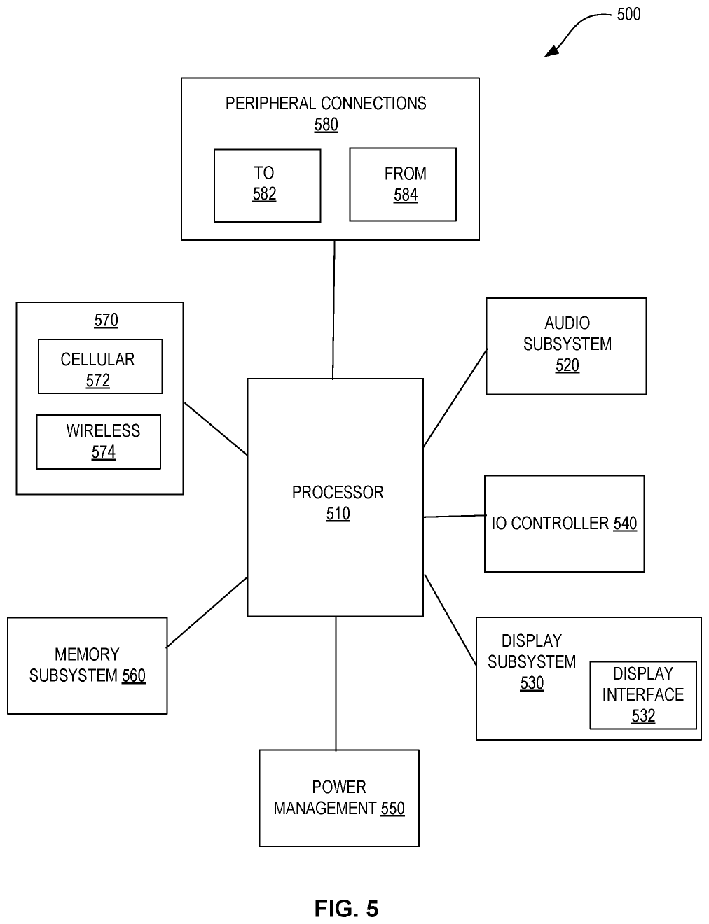

FIG. 5 illustrates a block diagram of computing device 500 comprising IC package 100 including an integrated TEC module (e.g., TEC module 108) adjacent and thermally coupled to an IC device (e.g., IC device 107) as part of a system-on-chip (SoC) package in an implementation of a computing device, according to some embodiments of the disclosure.

According to some embodiments, computing device 500 represents a server, a desktop workstation, or a mobile workstation, such as, but not limited to, a laptop computer, a computing tablet, a mobile phone or smart-phone, a wireless-enabled e-reader, or other wireless mobile device. An IC package, such as, but not limited to, a single- or multi-core microprocessor (e.g., processor 510 representing a central processing unit (CPU) or a graphical processing unit (GPU)), comprising one or more dies, is mounted on a motherboard of computing device 500. The IC package may comprise vertically integrated multiple dies or stacked individual packages in a package-on-package (PoP) architecture. In all architectures, IC packages may dissipate a large amount of heat during burst activity periods, when large computing demands are placed on the CPU or GPU. Large power dissipation results in excess heat, necessitating an enhanced thermal solution. According to some embodiments, computing device 500 employs an IC package (e.g., package 100) having a TEC module (e.g., TEC module 108) mounted adjacent to the CPU or GPU (e.g., IC device 107) and thermally coupled thereto, as described above.

In some embodiments, computing device has wireless connectivity (e.g., Bluetooth and/or WiFi). It will be understood that certain components are shown generally, and not all components of such a device are shown in computing device 500.

The various embodiments of the present disclosure may also comprise a network interface within 570 such as a wireless interface so that a system embodiment may be incorporated into a wireless device, for example, cell phone or personal digital assistant.

According to some embodiments, processor 510 represents a CPU or a GPU, and can include one or more physical devices, such as microprocessors, application processors, microcontrollers, programmable logic devices, or other processing means. The processing operations performed by processor 510 include the execution of an operating platform or operating system on which applications and/or device functions are executed. The processing operations include operations related to I/O (input/output) with a human user or with other devices, operations related to power management, and/or operations related to connecting the computing device 500 to another device. The processing operations may also include operations related to audio I/O and/or display I/O.

In one embodiment, computing device 500 includes audio subsystem 520, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 500, or connected to the computing device 500. In one embodiment, a user interacts with the computing device 500 by providing audio commands that are received and processed by processor 510.

Display subsystem 530 represents hardware (e.g., display devices) and software (e.g., drivers) components that provide a visual and/or tactile display for a user to interact with the computing device 500. Display subsystem 530 includes display interface 532 which includes the particular screen or hardware device used to provide a display to a user. In one embodiment, display interface 532 includes logic separate from processor 510 to perform at least some processing related to the display. In one embodiment, display subsystem 530 includes a touch screen (or touch pad) device that provides both output and input to a user.

I/O controller 540 represents hardware devices and software components related to interaction with a user. I/O controller 540 is operable to manage hardware that is part of audio subsystem 520 and/or display subsystem 530. Additionally, I/O controller 540 illustrates a connection point for additional devices that connect to computing device 500 through which a user might interact with the system. For example, devices that can be attached to the computing device 500 might include microphone devices, speaker or stereo systems, video systems or other display devices, keyboard or keypad devices, or other I/O devices for use with specific applications such as card readers or other devices.

As mentioned above, I/O controller 540 can interact with audio subsystem 520 and/or display subsystem 530. For example, input through a microphone or other audio device can provide input or commands for one or more applications or functions of the computing device 500. Additionally, audio output can be provided instead of, or in addition to display output. In another example, if display subsystem 530 includes a touch screen, the display device also acts as an input device, which can be at least partially managed by I/O controller 540. There can also be additional buttons or switches on the computing device 500 to provide I/O functions managed by I/O controller 540.

In one embodiment, I/O controller 540 manages devices such as accelerometers, cameras, light sensors or other environmental sensors, or other hardware that can be included in the computing device 500. The input can be part of direct user interaction, as well as providing environmental input to the system to influence its operations (such as filtering for noise, adjusting displays for brightness detection, applying a flash for a camera, or other features).

In one embodiment, computing device 500 includes power management 550 that manages battery power usage, charging of the battery, and features related to power saving operation. Memory subsystem 560 includes memory devices for storing information in computing device 500. Memory can include nonvolatile (state does not change if power to the memory device is interrupted) and/or volatile (state is indeterminate if power to the memory device is interrupted) memory devices. Memory subsystem 560 can store application data, user data, music, photos, documents, or other data, as well as system data (whether long-term or temporary) related to the execution of the applications and functions of the computing device 500.

Elements of embodiments are also provided as a machine-readable medium (e.g., memory 560) for storing the computer-executable instructions. The machine-readable medium (e.g., memory 560) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

Connectivity via network interface 570 includes hardware devices (e.g., wireless and/or wired connectors and communication hardware) and software components (e.g., drivers, protocol stacks) to enable the computing device 500 to communicate with external devices. The computing device 500 could be separate devices, such as other computing devices, wireless access points or base stations, as well as peripherals such as headsets, printers, or other devices.

Network interface 570 can include multiple different types of connectivity. To generalize, the computing device 500 is illustrated with cellular connectivity 572 and wireless connectivity 574. Cellular connectivity 572 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 574 refers to wireless connectivity that is not cellular, and can include personal area networks (such as Bluetooth, Near Field, etc.), local area networks (such as Wi-Fi), and/or wide area networks (such as WiMax), or other wireless communication.

Peripheral connections 580 include hardware interfaces and connectors, as well as software components (e.g., drivers, protocol stacks) to make peripheral connections. It will be understood that the computing device 500 could both be a peripheral device (“to” 582) to other computing devices, as well as have peripheral devices (“from” 584) connected to it. The computing device 500 commonly has a “docking” connector to connect to other computing devices for purposes such as managing (e.g., downloading and/or uploading, changing, synchronizing) content on computing device 500. Additionally, a docking connector can allow computing device 500 to connect to certain peripherals that allow the computing device 500 to control content output, for example, to audiovisual or other systems.

In addition to a proprietary docking connector or other proprietary connection hardware, the computing device 500 can make peripheral connections 580 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

The following examples pertain to further embodiments. Specifics in the examples may be used anywhere in one or more embodiments. All optional features of the apparatus described herein may also be implemented with respect to a method or process.

Example 1 is an integrated circuit package comprising a substrate comprising a dielectric; an IC device coupled to the substrate; and a thermoelectric cooling (TEC) device adjacent to the IC device and coupled to the substrate, wherein a thermal trace extends laterally on or within the dielectric between the TEC device to the IC device, and wherein the thermal trace is coupled to the TEC device and the IC device.

Example 2 includes all of the features of example 1, wherein the thermal trace comprises any one of copper, silver, gold, nickel, aluminum, silicon, or aluminum nitride.

Example 3 includes all of the features of examples 1 or 2, wherein the thermal trace has a depth dimension orthogonal to a width dimension, wherein the depth dimension is at least one half of the width dimension.

Example 4 includes all of the features of any one of examples 1 to 3, wherein the TEC device comprises a first surface and an opposing second surface, wherein the second surface is adjacent to the substrate, wherein a first metal layer is over the first surface and a second metal layer is over the second surface, the first metal layer is adjacent to a thermal solution over the TEC device.

Example 5 includes all of the features of any one of examples 1 to 4, wherein a thermal interface material is between the first surface of the TEC and the thermal solution.

Example 6 includes all of the features of example 5, wherein the thermal solution is a heat sink or an integrated heat spreader and a heat sink, wherein the heat sink is over the integrated heat spreader and thermally coupled thereto.

Example 7 includes all of the features of any one of examples 1 to 6, wherein the TEC device comprises a thermoelectric material, wherein the TEC device has a first surface over an opposing second surface, wherein the first surface and the second surface extend in a first direction from a first sidewall to an opposing second sidewall, and extend from a third sidewall to an opposing fourth sidewall in a second direction orthogonal to the first direction, and wherein the TEC device comprises multiple regions that are between the first sidewall and the second sidewall and are between the third sidewall and the fourth sidewall, and wherein the multiple regions comprise regions that comprise a n-type thermoelectric material alternating with regions that comprise a p-type thermoelectric material.

Example 8 includes all of the features of example 7, wherein the multiple regions comprise a first array of regions that comprise a n-type thermoelectric material, wherein the first array of regions extends in the first direction and the second direction, and interpenetrates a second array of regions such that regions of the first array alternate with regions of the second array, wherein the second array of regions extends in the first direction and the second direction, and wherein the second array of regions comprise a p-type thermoelectric material.

Example 9 includes all of the features of example 8, wherein a first conductive layer extends over the first surface and a second conductive layer extends over the second surface, the first conductive layer comprises a first island that extend between a first n-type region and a first p-type region adjacent to the first n-type region, wherein the first n-type region is electrically coupled to the first p-type region, wherein the second conductive layer comprises a second island that extends between the first n-type region and a second p-type region adjacent to the first n-type region, and wherein the second conductive layer comprises a third island that extends between the first p-type region and a second n-type region adjacent to the first p-type region, and wherein the first n-type region is electrically coupled to the second p-type region, and the first p-type region is electrically coupled to the second n-type region.

Example 10 includes all of the features of example 9, wherein one or more solder joints are between the second conductive layer of the TEC device and the thermal trace, where the second island and the third island are solder-bonded to a pad that extends to the thermal trace.

Example 11 includes all of the features of example 10, wherein the first conductive layer is thermally coupled to an integrated heat spreader.

Example 12 includes all of the features of any one of examples 7 to 11, wherein the thermoelectric material comprises any one of bismuth, antimony, lead, phosphorous, arsenic, silicon, germanium, strontium, titanium, oxygen, cobalt, niobium, hafnium, zirconium, selenium, tellurium, iron, nickel, gold, copper, indium, tin, gold, vanadium, manganese, zinc or rare earth elements.

Example 13 includes all of the features of any one of examples 1 to 12, wherein the IC device is solder-bonded to one or more pads extending from the at least one thermally conductive trace.

Example 14 is a system comprising a memory, a microprocessor coupled to the memory and in an IC package comprising a substrate comprising a dielectric; the microprocessor coupled to the substrate; and a thermoelectric cooling (TEC) device adjacent to the microprocessor and coupled to the substrate, wherein a thermal trace extends laterally on or within the dielectric between the TEC device to the microprocessor, and wherein the thermal trace is coupled to the TEC device and the microprocessor; a TEC controller circuit coupled to the TEC device; a thermal solution over the IC package; and a power source coupled to the microprocessor.

Example 15 includes all of the features of example 14, wherein the IC package is coupled to a wireless interface.

Example 16 includes all of the features of examples 14 or 15, an integrated heat spreader is between the microprocessor and the thermal solution, and wherein the thermal solution is a heat sink.

Example 17 includes all of the features of any one of examples 14 to 16, wherein the TEC controller is coupled to one or more temperature sensors that are within the microprocessor.

Example 18 is a method for making an IC package comprising receiving a substrate comprising a dielectric having one or more thermal traces extending within the dielectric between two or more thermal bond pads and coupled thereto; attaching an IC device to the substrate, such that the IC device is coupled to at least one of the two or more thermal bond pads; and attaching at least one TEC device to the substrate, wherein the at least one TEC device is coupled to at least one of the two or more thermal bond pads, wherein the at least one TEC device is thermally coupled to the IC device through the one or more thermal traces.

Example 19 includes all of the features of example 18, wherein attaching the at least one TEC device to the substrate comprises bonding the at least one TEC device adjacent to the IC package, wherein a first metal junction on the TEC device is bonded to at least one of the two or more thermal bond pads.

Example 20 includes all of the features of examples 18 or 19, wherein attaching at least one TEC device to the substrate comprises depositing a thermal interface layer on a second the at least one TEC device.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An Integrated Circuit (IC) package, comprising:
a substrate comprising a dielectric;
an IC device coupled to the substrate; and
a thermoelectric cooling (TEC) device adjacent to the IC device and coupled to the substrate,
wherein a thermal trace extends laterally on or within the dielectric between the TEC device to the IC device, and wherein the thermal trace is coupled to the TEC device and the IC device.

2. The IC package of claim 1, wherein the thermal trace comprises any one of copper, silver, gold, nickel, aluminum, silicon, or aluminum nitride.

3. The IC package of claim 1, wherein the thermal trace has a depth dimension orthogonal to a width dimension, wherein the depth dimension is at least one half of the width dimension.

4. The IC package of claim 1, wherein the TEC device comprises a first surface and an opposing second surface, wherein the second surface is adjacent to the substrate, wherein a first metal layer is over the first surface and a second metal layer is over the second surface, the first metal layer is adjacent to a thermal solution over the TEC device.

5. The IC package of claim 4, wherein a thermal interface material is between the first surface of the TEC and the thermal solution.

6. The IC package of claim 5, wherein the thermal solution is a heat sink or an integrated heat spreader and a heat sink, wherein the heat sink is over the integrated heat spreader and thermally coupled thereto.

7. The IC package of claim 1, wherein the TEC device comprises a thermoelectric material, wherein the TEC device has a first surface over an opposing second surface, wherein the first surface and the second surface extend in a first direction from a first sidewall to an opposing second sidewall, and extend from a third sidewall to an opposing fourth sidewall in a second direction orthogonal to the first direction, and wherein the TEC device comprises multiple regions that are between the first sidewall and the second sidewall and are between the third sidewall and the fourth sidewall, and wherein the multiple regions comprise regions that comprise a n-type thermoelectric material alternating with regions that comprise a p-type thermoelectric material.

8. The IC package of claim 7, wherein the multiple regions comprise a first array of regions that comprise a n-type thermoelectric material, wherein the first array of regions extends in the first direction and the second direction, and interpenetrates a second array of regions such that regions of the first array alternate with regions of the second array, wherein the second array of regions extends in the first direction and the second direction, and wherein the second array of regions comprise a p-type thermoelectric material.

9. The IC package of claim 8, wherein a first conductive layer extends over the first surface and a second conductive layer extends over the second surface, the first conductive layer comprises a first island that extend between a first n-type region and a first p-type region adjacent to the first n-type region, wherein the first n-type region is electrically coupled to the first p-type region, wherein the second conductive layer comprises a second island that extends between the first n-type region and a second p-type region adjacent to the first n-type region, and wherein the second conductive layer comprises a third island that extends between the first p-type region and a second n-type region adjacent to the first p-type region, and wherein the first n-type region is electrically coupled to the second p-type region, and the first p-type region is electrically coupled to the second n-type region.

10. The IC package of claim 9, wherein one or more solder joints are between the second conductive layer of the TEC device and the thermal trace, where the second island and the third island are solder-bonded to a pad that extends to the thermal trace.

11. The IC package of claim 10, wherein the first conductive layer is thermally coupled to an integrated heat spreader.

12. The IC package of claim 7, wherein the thermoelectric material comprises any one of bismuth, antimony, lead, phosphorous, arsenic, silicon, germanium, strontium, titanium, oxygen, cobalt, niobium, hafnium, zirconium, selenium, tellurium, iron, nickel, gold, copper, indium, tin, gold, vanadium, manganese, zinc or rare earth elements.

13. The IC package of claim 1, wherein the IC device is solder-bonded to one or more pads extending from the at least one thermally conductive trace.

14. A system, comprising:
a memory;
a microprocessor coupled to the memory, the microprocessor in an IC package comprising:
a substrate comprising a dielectric;
the microprocessor coupled to the substrate; and
a thermoelectric cooling (TEC) device adjacent to the microprocessor and coupled to the substrate,
wherein a thermal trace extends laterally on or within the dielectric between the TEC device to the microprocessor, and wherein the thermal trace is coupled to the TEC device and the microprocessor;
a TEC controller circuit coupled to the TEC device;
a thermal solution over the IC package; and
a power source coupled to the microprocessor.

15. The system of claim 14, wherein the microprocessor is coupled to a wireless interface.

16. The system of claim 14, wherein an integrated heat spreader is between the microprocessor and the thermal solution, and wherein the thermal solution is a heat sink.

17. The system of claim 14, wherein the TEC controller is coupled to one or more temperature sensors that are within the microprocessor.

18. A method for making an IC package, comprising:
receiving a substrate comprising a dielectric having one or more thermal traces extending within the dielectric between two or more thermal bond pads and coupled thereto;
attaching an IC device to the substrate, such that the IC device is coupled to at least one of the two or more thermal bond pads; and
attaching at least one TEC device to the substrate, wherein the at least one TEC device is coupled to at least one of the two or more thermal bond pads, wherein the at least one TEC device is thermally coupled to the IC device through the one or more thermal traces.

19. The method of claim 18, wherein attaching the at least one TEC device to the substrate comprises bonding the at least one TEC device adjacent to the IC package, wherein a first metal junction on the TEC device is bonded to at least one of the two or more thermal bond pads.

20. The method of claim 18, wherein attaching at least one TEC device to the substrate comprises depositing a thermal interface layer on a second the at least one TEC device.
